(19) United States
(12) Patent Application Publication
(10) Pub. No.: US 2014/0077269 A1
(43) Pub. Date: Mar. 20, 2014

(54) COMPACT REGULAR RECONFIGURABLE FABRICS

(71) Applicant: Bao Liu, San Antonio, TX (US)

(72) Inventor: Bao Liu, San Antonio, TX (US)

(73) Assignee: Board of Regents of the University of Texas System, Austin, TX (US)

(21) Appl. No.: 13/883,189

(22) PCT Filed: Nov. 2, 2011
(86) PCT No.: PCT/US11/58962

§ 371 Date: Nov. 21, 2013

Related U.S. Application Data
(60) Provisional application No. 61/409,209, filed on Nov. 2, 2010.

(51) Int. Cl. H01L 27/118; H01L 27/02

(52) U.S. Cl. CPC H01L 27/11807; H01L 27/0207
USPC 257/204

(57) ABSTRACT

Described herein are compact regular programmable fabrics for improved logic density, yield, reliability, performance and power consumption compared with existing programmable fabric based VLSI design. Programmable fabrics facilitate technology transition from current silicon lithographic VLSI design to future non-silicon self-assembled nanoscale device based VLSI design.

### BACKGROUND OF THE INVENTION

1. Field of the Invention

The invention generally relates to configurable programmable semiconductor devices.

2. Description of the Relevant Art

As VLSI technology scales into the nanometer domain, the minimum layout feature size becomes less than photolithography wavelength, traditional VLSI manufacturing process can no longer achieve desired resolution. Optical Proximity Correction (“OPC”) and other Design for Manufacture (“DFM”) techniques enhance layout resolution by inserting auxiliary layout features. As technology scales, such auxiliary layout features become increasingly complex, leading to increased process variables or design uncertainties which hinder design closure. This lengthened design cycle combined with skyrocketing mask costs have prevented an increasing number of VLSI designs from moving to the most advanced technologies.

Existing silicon based programmable Very Large Scale Integration (“VLSI”) fabrics include early Programmable Logic Devices (“PLDs”) such as Programmable Array Logic (“PAL”) devices, Programmable Logic Array (“PLA”) devices, Complex Programmable Logic Devices (“CPLDs”) and later Field-Programmable Gate Array (“FPGA”) devices, structured Application-Specific Integrated Circuits (“ASIC”), and Via-Patterned Gate Arrays (VPGA). A FPGA includes two programmable areas: logic blocks and routing switches. These programmable areas are arranged by various manufacturers in, for example: a symmetric array; row-based; sea-of-gates; or hierarchical-PLD layout style. The logic blocks are based on: lookup tables; multiplexers; or PLD. The routing switches are implemented by multiplexers or anti-fuses. Programmability is provided by SRAM, anti-fuse, EPROM, or EEPROM. A structured ASIC is pre-fabricated with a variety of IP blocks. A customer finishes the design by programming the top level metals and vias, achieving fast turnaround time and reduced non-recurring engineering cost, with close-to-ASIC performance and power consumption. Via programmable gate arrays provide pre-fabricated lookup table (or PLB) based logic blocks and interconnects, much like FPGAs, while relying on vias for customization. These existing programmable VLSI fabrics achieve reduced design cost and turnaround time. However, they are based on complex layout patterns, which are not expected to achieve satisfiable yield as technology continues to scale down.

A new breed of lithography-friendly compact regular programmable fabrics (e.g., based on a simple regular structure) are much needed to achieve much improved logic density, yield, reliability, performance and power consumption for programmable fabric based VLSI designs, e.g., comparable to their ASIC counterparts.

### SUMMARY OF THE INVENTION

Described herein are reconfigurable fabrics for sublithographic silicon VLSI circuits. Sublithographic fabrics are typically based on a regular layout pattern which is as simple as possible for minimum manufacturing complexity and maximum device density, yield, and reliability. Embodiments herein relate to configurable fabric layouts that may be used for sublithographic reconfiguration.

In an embodiment, a reconfigurable fabric includes alternative rows of PMOS/NMOS floating-gate transistors in a series, with alternative programmable vias formed by anti-fuses or branched-out floating-gate transistors coupled to orthogonal metal wires, wherein a floating-gate transistor is reconfigurable to open, short, or a transistor, a programmable via is reconfigurable to be open or via, by the same programming methods as for NAND flash memory and/or anti-fuse based FPGAs. The reconfigurable fabric may include horizontal/vertical polysilicon/metal wires of different lengths, which are connected by programmable vias (formed by anti-fuses or flash memory floating-gate transistors). The reconfigurable fabric may also include floating-gate pass transistors which couple polysilicon and metal wires and form a crossbar structure in programming, and are turned off in circuit operation, with possible additional floating-gate pass transistors which isolate an anti-fuse during programming. In an embodiment, a reconfigurable fabric may be configured as address decoders of a binary decoder circuit or a hybrid of a binary decoder indicating the least-significant bits and a voltage-controlled nano-addressing circuit indicating the most-significant bits, which includes two address lines as resistive voltage dividers, gating the orthogonal date lines via two rows of transistors.

### BRIEF DESCRIPTION OF THE DRAWINGS

Advantages of the present invention will become apparent to those skilled in the art with the benefit of the following detailed description of embodiments and upon reference to the accompanying drawings in which:

FIG. 1 depicts rows of PMOS/NMOS floating-gate transistors in a series, with alternative programmable vias formed by anti-fuses coupling to orthogonal metal wires;

FIG. 2 depicts rows of PMOS/NMOS floating-gate transistors in a series, with alternative programmable vias formed by branched-out floating-gate transistors coupling to orthogonal metal wires;

FIG. 3A depicts a combinational logic a(b+c) implemented in a compact reconfigurable fabric including both PMOS and NMOS floating-gate transistors, while programmable vias are based on either anti-fuses or floating gate transistors;

FIG. 3B depicts a latch implemented in a compact reconfigurable fabric including both PMOS and NMOS flash memory floating-gate transistors, while programmable vias are based on either anti-fuses or floating gate transistors;

FIG. 4A depicts wire segments coupled by pass transistors to a crossbar, through which positive (V+) and negative (V−) voltages are applied;

FIG. 4B depicts a floating-gate transistor or a via isolated by the pass transistors, positive and negative voltages are applied from dedicated power/ground wires;

FIG. 5 depicts a novel voltage-controlled nano-addressing circuit;

FIG. 6 depicts a uniform array of programmable devices-based uniform compact regular reconfigurable computing platform;

FIG. 7 depicts a compact floating-gate transistor arrays (FGTAs) and programmable/fixed vias-based compact regular reconfigurable computing platform;

FIG. 8A depicts a CMOS static logic implementation for a 3-input NAND gate;

FIG. 8B depicts a LUT-based logic implementation for a 3-input NAND gate;

FIG. 9 depicts a 4-input NAND gate in a compact FGTA; and

FIG. 10 depicts a 1-bit full adder in a compact FGTA.

While the invention may be susceptible to various modifications and alternative forms, specific embodiments thereof are shown by way of example in the drawings and will herein be described in detail. The drawings may not be to scale. It should be understood, however, that the drawings and detailed description thereto are not intended to limit the invention to the particular form disclosed, but to the contrary, the intention is to cover all modifications, equivalents, and alternatives falling within the spirit and scope of the present invention as defined by the appended claims.

### DETAILED DESCRIPTION OF THE PREFERRED EMBODIMENTS

It is to be understood the present invention is not limited to particular devices or methods, which may, of course, vary. It is also to be understood that the terminology used herein is for the purpose of describing particular embodiments only, and is not intended to be limiting. As used in this specification and the appended claims, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected.

As VLSI technology continues to scale beyond the end of the roadmap for silicon based technologies, VLSI design is expected to be based on non-silicon nanoscale devices, e.g., carbon nanotubes (CNTs) and carbon nanotube field effect transistors (CNFETs). Such nanoscale devices are expected to be manufactured based on bottom-up self-assembly processes, rather than the traditional top-down lithography based VLSI manufacturing process. Self-assembly provides only regular structures, e.g., perfectly aligned carbon nanotube arrays. As a result, non-silicon self-assembled nanoelectronic systems may rely on programmability to achieve functionality and reliability.

Compact regular programmable fabrics described herein may be used for sublithographic silicon VLSI circuits. Such fabrics are typically based on a regular layout pattern which is as simple as possible for minimum manufacturing complexity and maximum device density, yield, and reliability. Examples of nanoscale devices are described in U.S. Pat. Nos. 7,737,471 and 7,630,227; and PCT Application Nos. WO 2005/112264 and WO 2007/059630, and in the paper to Kang et al. “High-performance electronics using dense, perfectly aligned arrays of single-walled carbon nanotubes” Nature Nanotechnology, 2: 230-236, 2007 all of which are incorporated herein by reference.

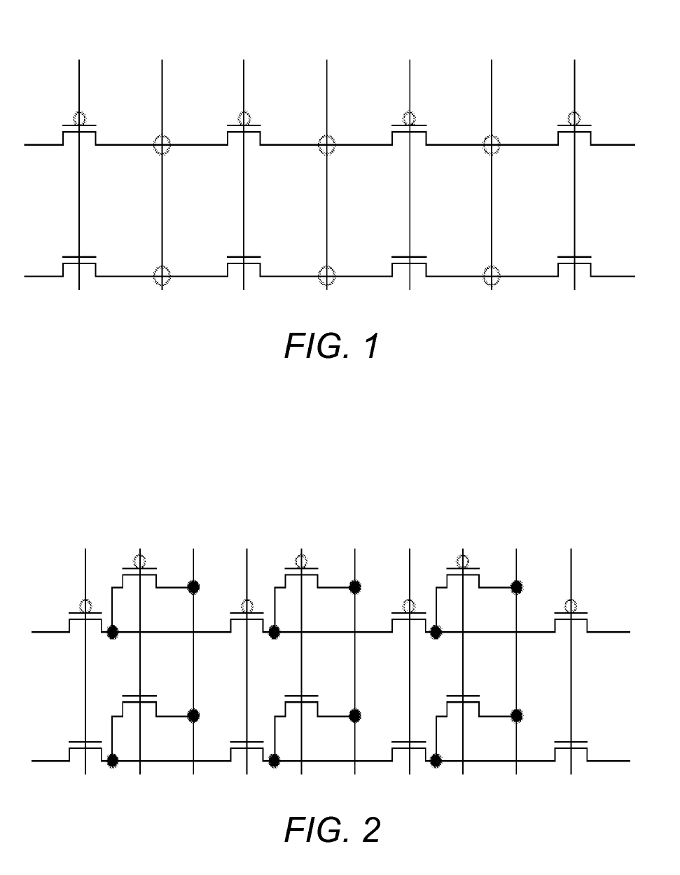

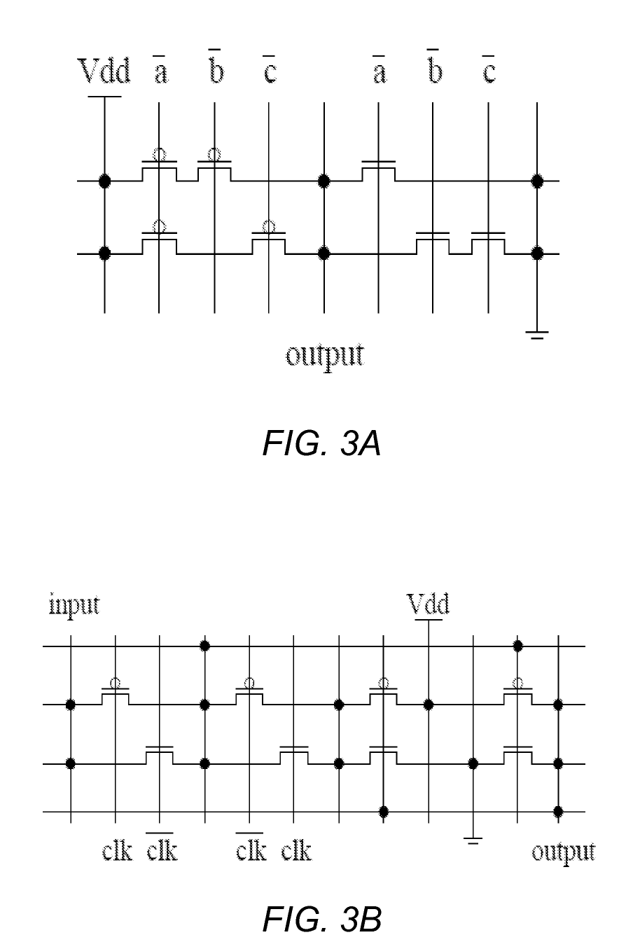

Described herein are embodiments of fabrics that may be used to allow programming of patterned nanoscale devices. FIG. 1 is an illustration of a compact regular reconfigurable fabric including PMOS and NMOS floating-gate transistors for logic implementation and (e.g., anti-fuse based) programmable vias for routing configuration. FIG. 2 is an illustration of a compact regular reconfigurable fabric including PMOS and NMOS floating-gate transistors for both logic implementation and routing configuration.

A floating-gate transistor includes a control gate and a floating gate. Programming is achieved by applying an elevated on-voltage to the control gate and a large current through the transistor channel, such that the hot-carrier injection effect takes place, e.g., accelerated high energy charge carriers in the transistor channel penetrate the gate oxide and become trapped in the floating gate, leading to an increased transistor threshold voltage, and a constantly off transistor. Erasing is achieved by applying a large voltage to the control gate to pull out the trapped carriers in the floating gate.

Floating-gate transistors form the building blocks of EEPROMs and flash memories, wherein they are connected either in series or in parallel in NAND or NOR flash memories, respectively. NAND flash memories achieve more compact layout design than NOR flash memories. Programming in a NAND flash memory is achieved by applying an elevated on-voltage to the control gate of the floating-gate transistor under programming, and applying an on-voltage to other transistors in series to conduct a large current.

Due to their regular layout pattern, flash memories achieve higher yield and enjoy better technology scaling than FPGAs (e.g., 22 nm flash memories and 40/45 nm FPGAs are available as of today, respectively). Industrial EEPROMs and flash memories are based on NMOS FG transistors for performance, while PMOS FG transistors are also available.

Anti-fuses are one-time programmable vias. For example, in the QuickLogic ViaLink technology, an anti-fuse includes a layer of amorphous silicon sandwiched between two layers of metal. A 10V programming voltage melts the structure into a polycrystalline silicon-metal alloy, and provides a resistance difference between ˜1 GΩ and 80Ω.

In this fabrics depicted in FIGS. 1 and 2, rows of PMOS/NMOS floating-gate transistors in a series, with alternative programmable vias formed by anti-fuses (FIG. 1) or branched-out floating-gate transistors (FIG. 2) coupling to orthogonal metal wires, wherein a floating-gate transistor is reconfigurable to open, short, or a transistor, a programmable via is reconfigurable to be open or via. Programmable opens are based on gate isolation (as in sea-of-gates designs) in a diffusion row.

Polysilicon and metal wires at all routing layers of different lengths are provided for short, intermediate and long interconnects. These wires may be connected by programmable vias on the same layer or between two adjacent layers. Programmable vias are based on anti-fuses or floating-gate transistors. For floating-gate transistor based programming vias, wires need to be on the metal 1 layer at least partly. For anti-fuse based programmable vias, wires can be totally on the upper layers.

Additional floating-gate pass transistors couple horizontal and vertical polysilicon and metal wires into a crossbar structure. During programming, the floating-gate pass transistors are turned on, forming a crossbar of polysilicon and metal wires to access every programmable component. After programming, some of the floating-gate pass transistors are turned off, providing opens. Programming serialized floating-gate transistors may be performed using the same methodology as programming a NAND flash memory. Programming anti-fuses may be performed using the same methodology as in the existing anti-fuse based FPGAs.

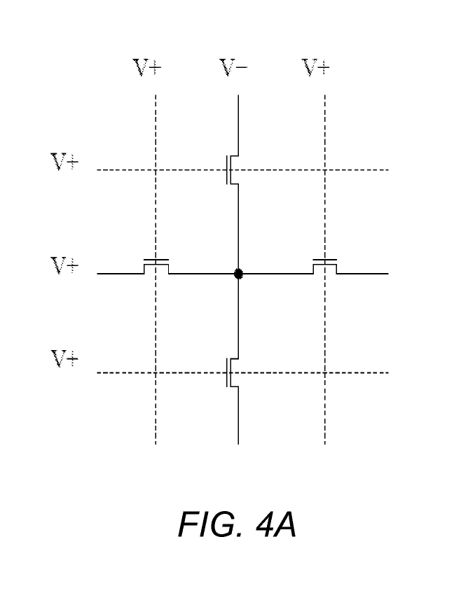

A compact reconfigurable fabric, as depicted in FIGS. 1 and 2, provides high logic density implementations for all combinational logic families, including CMOS static logic (e.g., in FIG. 3A), domino logic, pass-transistor logic, etc., as well as sequential elements including latches, (e.g., in FIG. 3B), flip-flops, and memories. For example, FIG. 3A depicts a combinational logic a(b+c) implemented in a compact reconfigurable fabric including both PMOS and NMOS floating-gate transistors, while programmable vias are based on either anti-fuses or floating gate transistors. FIG. 3B depicts a latch implemented in a compact reconfigurable fabric including both PMOS and NMOS flash memory floating-gate transistors, while programmable vias are based on either anti-fuses or floating gate transistors.

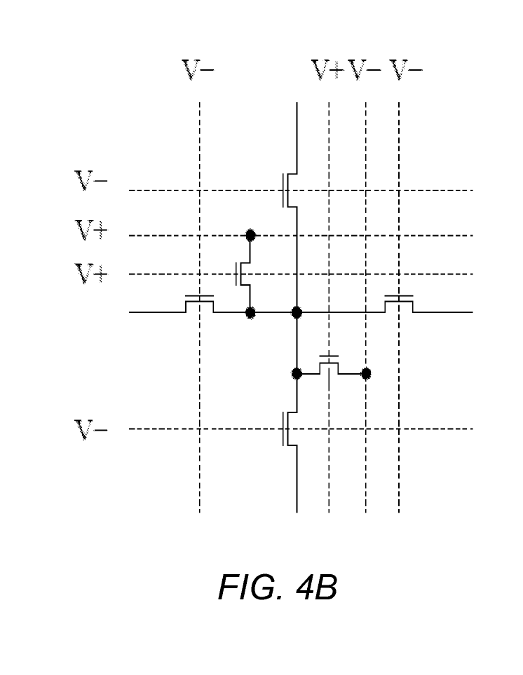

Programming a floating-gate transistor or a programmable via can be achieved by applying positive and negative voltages through the fabric, with all floating-gate transistors turned on in the paths from a programming voltage source to the floating-gate transistor or the via to program. FIG. 4A depicts wire segments coupled by pass transistors to a crossbar fabric, through which positive (V+) and negative (V−) voltages are applied.

FIG. 4B depicts a more complex and reliable programming circuit that isolates a floating-gate transistor or a programmable via with the (other) transistors in the fabric. Floating-gate transistors, which couple polysilicon and metal wires and form a crossbar structure in programming, are turned off in circuit operation, which possible additional floating-gate pass transistors which isolate a floating-gate transistor or a via to program. The four floating-gate pass transistors around the floating-gate transistor or the via to program are open during programming, isolating the floating-gate transistor or the via to program. Positive and negative voltages are applied through additional wires which are dedicated to programming. FIG. 4B depicts a floating-gate transistor or a programmable via isolated by the pass transistors, positive (V+) and negative (V−) voltages are applied from dedicated power/ground wires.

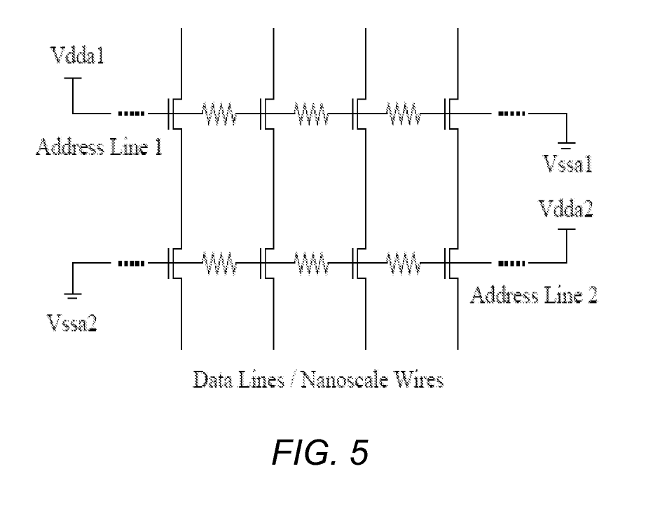

FIG. 5 shows a novel voltage-controlled nano-addressing circuit, which is based on a regular layout, including two address lines (of either microscale or nanoscale wires) as voltage dividers, which provide gate voltages for two rows of transistors which gate the nanoscale data lines. This voltage-controlled nano-addressing circuit can be combined with the traditional binary decoder based addressing circuit to address the wires in the proposed compact regular reconfigurable fabric. FIG. 5, specifically, depicts address decoders of a binary decoder circuit or a hybrid of a binary decoder indicating the least-significant bits and a voltage-controlled nano-addressing circuit indicating the most-significant bits, which includes two address lines as resistive voltage dividers, gating the orthogonal date lines via two rows of transistors.

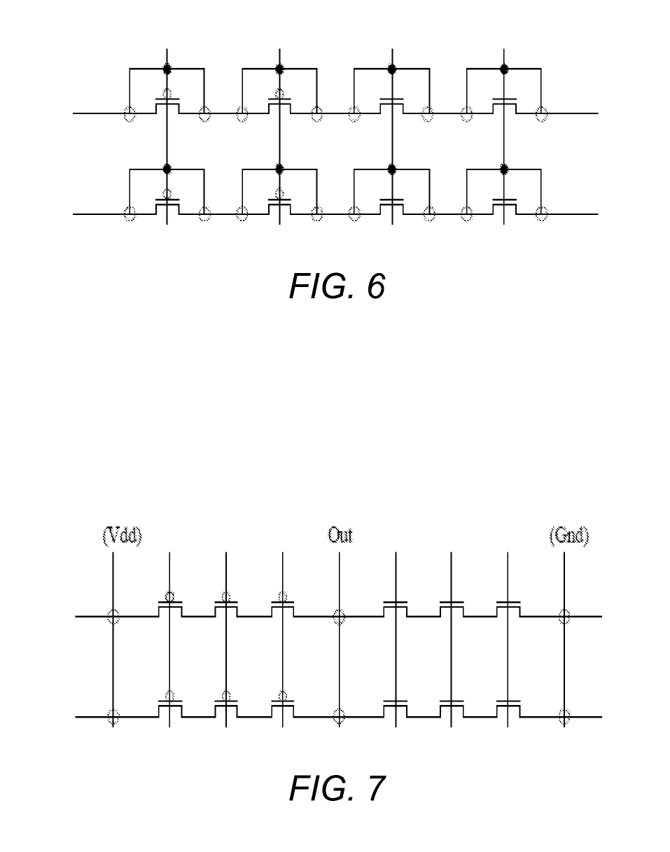

The CNT crossbar nano-architecture provides a promising nanoscale reconfigurable computing platform, achieving manufacturability (yield) by regularity, reliability by reconfigurability, performance by logic (device) density. Although current nanotechnology development has not achieved realization of the building block device of RDG-CNFET (reconfigurable double-gate carbon nanotube field-effect transistor), it is possible to achieve similar compact regular programmable fabrics for nanoscale reconfigurable computing by replacing a RDG-CNFET with available devices, for example, a floating-gate transistor and two programmable vias, as depicted in FIG. 6. The floating-gate transistor is configurable to be open, short, or a transistor. The programmable vias are programmable to be open or a via between two adjacent routing layers. They can be based on anti-fuse or floating-gate transistor technology as in today's FPGAs. This gives a uniform array of reconfigurable devices.

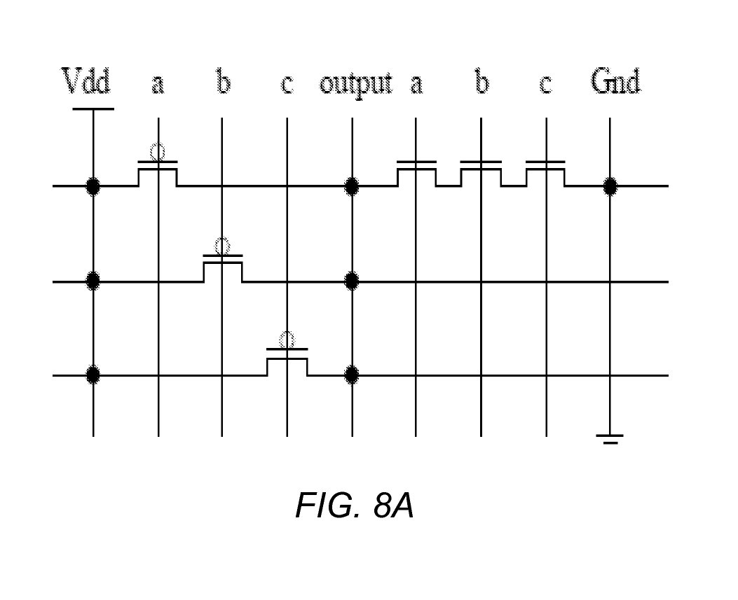

FIG. 7 depicts a compact floating-gate transistor arrays and programmable/fixed vias-based compact regular reconfigurable computing platform that includes: (a) floating-gate transistor arrays with fixed power, ground, and output routings, and a fixed number (e.g., three or four) of inputs within a cell, and (b) pre-routed interconnects of various lengths, which are connected by programmable vias. The floating-gate transistors are reconfigurable to open, short, or a transistor. The programmable vias are reconfigurable to be open or via (e.g., based on an anti-fuse or a floating-gate transistor as in current FPGAs, e.g., by the same programming methods as for NAND flash memory and/or current FPGAs).

There are a number of degrees of freedom to optimize this nanoscale computing platform, and achieve variant nanoarchitectures, which can serve as an equivalent reconfigurable computing platform for general-purpose or application-specific integrated circuits.

For example, alternating floating-gate transistors and programmable vias, depicted in FIG. 1 gives a straightforward variant nanoarchitecture. Compared with the nano-architecture depicted in FIG. 6, which takes RDG-CNFET as three integrated devices (a floating-gate transistor and two programmable vias), this variant nano-architecture reduces the number of devices to implement a given logic function, leading to improved logic density. On the other hand, disintegrating complex (e.g., RDG-CNFET) devices into simple devices reduces manufacture complexity (e.g., avoiding the double gate alignment problem). However, alternating floating-gate transistors and programmable vias requires a very high layout resolution at nanometer scale, or, the achievable layout resolution limits the achievable logic density based on this nano-architecture.

Combining programmable vias with compact floating-gate transistor arrays (FGTAs) improves layout resolution: lithography defines regions of programmable vias, which are sparse so that the required layout resolution is achievable at nanometer technologies. Improved logic density may also be achieved since unnecessary vias are avoided. Logic synthesis and FPGA architecture research has shown that 3(4)-input logic cells or LUTs achieve the highest logic density.

Further, certain programmable vias may be replaced by fixed vias for each logic cell (and combine 3-input programmable logic cells with 4-input programmable logic cells on a reconfigurable computing platform as modem FPGAs do). This further reduces manufacture cost and layout area in some technologies (e.g., with anti-fuse-based programmable vias).

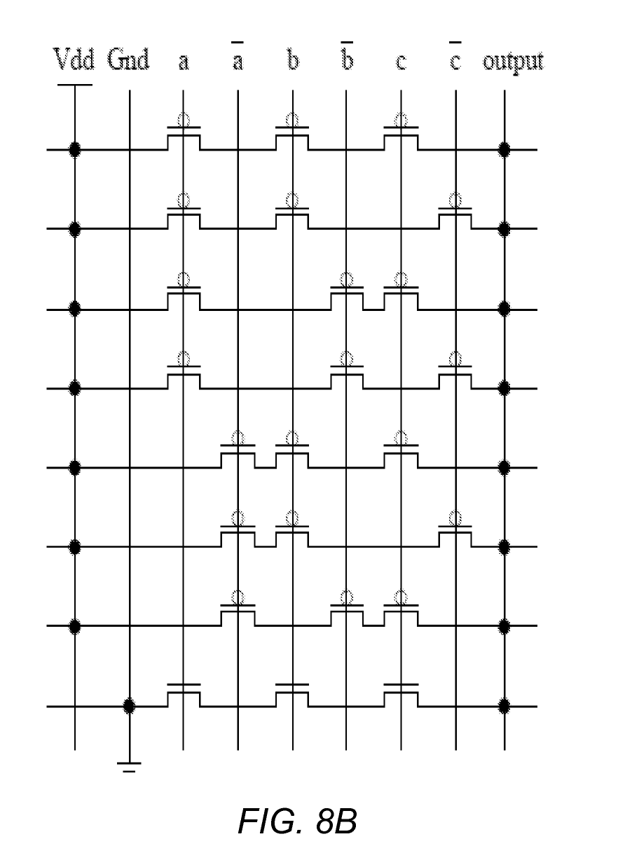

These variant nanoscale computing platforms are able to implement a variety of logic families, including CMOS static logic (FIG. 8A) and lookup table (LUT)-based logic (FIG. 8B). The capability of implementing a variety of logic families (especially achieving reconfigurable CMOS static logic in a floating-gate transistor array) allows us to achieve further optimized nanoscale circuits.

Logic cells in a FGTA are preferred to have their power/ground supply nets routed on the cell boundaries. Instances of such cells can be placed abut such that they share their power/ground supply. Otherwise, physically neighboring gates may be separated either by separate p- or n-wells, or by gate isolation, i.e., applying an off-voltage to a pass transistor, as in sea-of-the-gate designs.

A floating-gate transistor array (FGTA) includes alternative rows of PMOS or NMOS floating-gate transistors in series, which are coupled to each other by their diffusion regions directly; and programmable vias such as anti-fuses or branched-out floating-gate transistors, which couple to orthogonal vertical metal wires. These rows are separated by routing channels, similar to a gate array or other existing row-based layouts. In the routing channels and on the upper routing layers are metal wire segments of different lengths (for short, median, and long interconnects), which are connected by a minimum number of anti-fuses or branched-out floating-gate transistors for high performance. Feedthroughs are achieved by programming the vias in a column open in a FGTA with anti-fuses, or by programming the branched-out transistors open, and the serial transistors short in a column in a purely floating-gate-transistor-based FGTA.

Programming of floating-gate transistors are similar to in a NAND flash memory, e.g., an elevated on-voltage is applied to the floating-gate transistor to program, and on-voltages are applied to the other transistors in series to conduct a large current.

### Experiments

### A. Device Integration and Cell Granularity

To evaluate the proposed variant CNT crossbar nanoscale computing platforms, the number of devices for implementing a logic function on these platforms (e.g., FIGS. 1, 2, 6, and 7) is implemented.
1. To implement an n-input logic function on an RDG-CNFET-based platform, we need an array of m×(n+2)RDG-CNFETs, where m is the number of rows (e.g., for LUT-based logic, m=2n), each row includes n p-type or n-type RDG-CNFETs and two vias, one for the output, the other for the power or the ground. Suppose each RDG-CNFET has an layout area of a times of a floating-gate transistor (e.g., a α≈3 since each RDG-CNFET includes one floating gate-transistor and two programmable vias), we have a cost of αm(n+2) for implementing an n-input logic function.
2. To implement an n-input logic function on an alternating floating-gate transistors and programmable vias-based platform, we need an array of m×(2n+1) floating-gate transistors and programmable vias, where m is the number of rows, each row includes n floating gate transistors and n+1 programmable vias.
3. To implement an n-input logic function in a compact FGTA and programmable/fixed via-based nano-architecture, we need an array of m×(n+2) floating-gate transistors and programmable/fixed vias, where m is the number of rows, each row includes n floating-gate transistors and two programmable/fixed vias, one for the output, the other for the power or the ground.

In practice, p-type and n-type floating-gate transistor arrays can be on both sides of the output CNT (instead of on one side of the output CNT), leading to via colliding hence reduced device count and layout area. We list the device counts for these variant computing platforms in general and for a group of example logics (3-input NAND, 4-input NAND, the carry-out logic and the sum logic of a 1-bit full adder) in Table I. Note that because of via colliding, there is one less via for NAND3, NOR3, NAND4, and NOR4, three and four less vias for the carry-out and the sum logic of the 1-bit adder than the formulated estimates, respectively.

TABLE I
NUMBER OF DEVICES (FLOATING-GATE TRANSISTORS AND
PROGRAMMABLE/FIXED VIAS) NEEDED FOR A GROUP OF
SIMPLE CMOS STATIC LOGIC IMPLEMENTATIONS ON
VARIANT CROSSBAR NANOSCALE COMPUTING PLATFORMS.

| Circuit | m | n | Uniform | Alternating | Compact |
|---|---|---|---|---|---|
| NAND3 | 4 | 3 | 19α | 27 | 19 |
| NOR3 | 4 | 3 | 19α | 27 | 19 |
| 1-Bit Adder Cₒᵤₜ | 6 | 3 | 27α | 39 | 27 |
| NAND4 | 5 | 4 | 29α | 44 | 29 |
| NOR4 | 5 | 4 | 29α | 44 | 29 |
| 1-Bit Adder Sum | 8 | 4 | 44α | 68 | 44 |

Uniform nano-architecture or a compact FGTAs and vias-based nano-architecture requires the minimum number of devices in logic implementation and achieves maximum logic density. However, the single kind of reconfigurable devices (RDG-CNFETs) in a uniform nano-architecture is more complex than the floating-gate transistors and programmable/fixed vias in a compact FGTAs and vias-based nano-architecture. This leads to increased manufacture complexity (e.g., to align the front gate CNT and the back gate CNT), and reduced logic density in a 3-D perspective (since each RDG-CNFET occupies three layers while floating-gate transistors and programmable/fixed vias occupy two layers).

These nano-architectures have very close electrical properties (e.g., performance and power). Table II summarizes these variant nano-architectures. The advantages in manufacture complexity and logic density certainly favor compact FGTAs and vias-based nano-architectures (FIG. 7).

TABLE II
METRICS OF VARIANT CROSSBAR NANOSCALE
COMPUTING PLATFORMS.

| | Manufacture | Logic | | |
|---|---|---|---|---|
| Platform | Complexity | Density | Performance | Power |
| Uniform | Medium | Medium | Same | Same |
| Alternating | High | Low | Same | Same |
| Compact | Low | High | Same | Same |

Next, CMOS static logic and LUT-based logic in CNT and silicon technologies (based on compact FGTA nanoarchitectures) was compared. In silicon technology, CMOS static logic is the dominant logic in ASIC design, while LUT-based logic is the dominant logic in FPGA design. In the studied nanoscale computing platforms, reconfigurable CMOS static logic was compared with LUT-based logic to determine the optimum circuit paradigm in CNT technology.

Floating-gate transistors in CNT technology were modeled by the Stanford compact CNFETModel (Predictive technology model, http://www.eas.asu.edu/˜ptm/), and floating-gate transistors in silicon technology was modeled by the 16 nm high performance Predictive Technology Model (Stanford cnfet compact model, http://nano.stanford.edu/models.php/). For equal comparison, we tuned several parameters in the Stanford compact CNT model, such that a CNFET has the same layout area as a MOSFET. A programmable on-transistor was modeled as a high voltage (Vdd) gated transistor. A programmable via was modeled as a resistor having an 80Ω or infinite resistance.

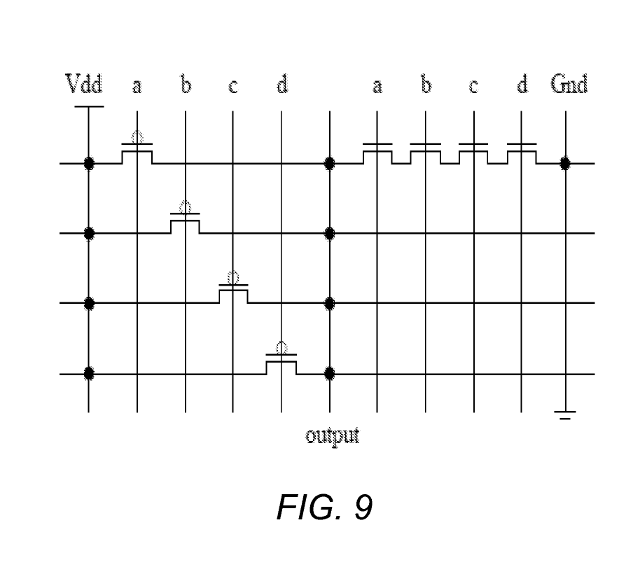

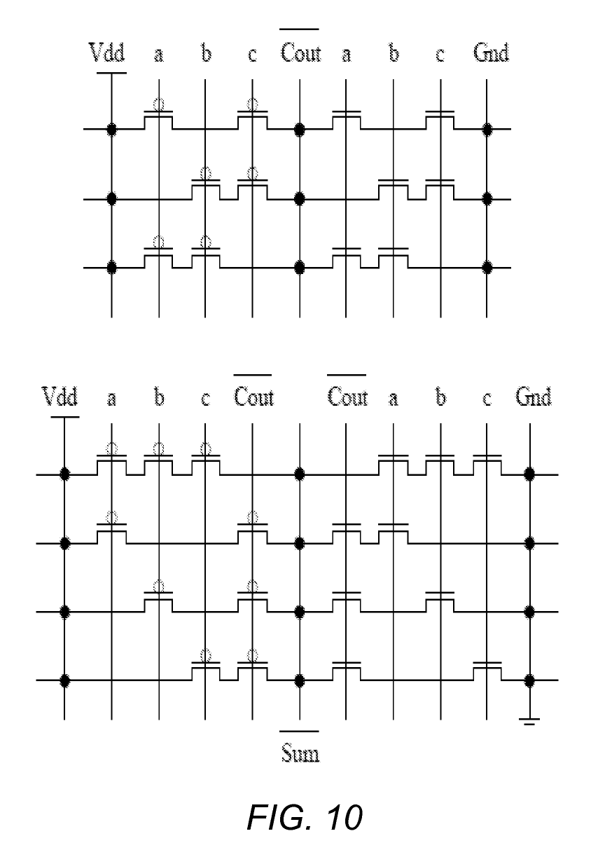

FIG. 8A depicts an embodiment of a CMOS static logic implementation for a 3-input NAND gate. FIG. 8B depicts an embodiment of a LUT-based logic implementation for a 3-input NAND gate. FIG. 9 depicts an embodiment of a 4-input NAND gate. FIG. 10 depicts an embodiment of a 1-bit full adder in a compact FGTA.

Table III compares CMOS static logic and LUT-based logic implementations for a number of 3- and 4-input Boolean logic functions including NAND, NOR, and 1-bit full adder in terms of device count, performance, and power consumption, respectively. CMOS static logic dominates LUT-based logic in terms of all design metrics, including device count, performance, and power consumption, for all benchmark circuits in the experiment. In CNT technology, CMOS static logic achieves an average of 42.2% device count, 71.3% signal propagation delay, and 22.0% power consumption compared with LUT-based logic for 3-input logic functions, and an average of 27.5% device count, 77.3% signal propagation delay, and 13.0% power consumption compared with LUT-based logic for 4-input logic functions. In 16 nm silicon technology, CMOS static logic achieves an average of 42.2% device count, 65.22% signal propagation delay, and 28.49% power consumption compared with LUT-based logic for 3-input logic functions, and an average of 27.5% device count, 84.75% signal propagation delay, and 22.19% power consumption compared with LUT-based logic for 4-input logic functions.

In summary, CMOS static logic dominates LUT-based logic for both CNT and silicon technologies in terms of area, performance, and power consumption. Achieving reconfigurable CMOS static logic allows a floating-gate transistor array to achieve reduced area, improved performance and reduced power consumption compared with LUT-based logic.

TABLE III
TRANSISTOR AND VIA COUNT #Dav, CRITICAL PATH DELAY FOR
RISING AND FALLING SIGNAL TRANSITIONS Dᵣᵢₛₑ AND D_{fall}(ps),
AND POWER CONSUMPTION P(nW) FOR NAND3, NOR3, NAND4,
NOR4, AND THE CARRY-OUT LOGIC AND THE SUM LOGIC OF A
1-BIT FULL ADDER IMPLEMENTED IN CMOS STATIC LOGIC AND
LUT-BASED LOGIC IN CNT AND 16 NM SILICON TECHNOLOGIES,
RESPECTIVELY.

| | | | | Dᵣᵢₛₑ | D_{fall} | Power | D × P |
|---|---|---|---|---|---|---|---|
| Circuit | Technology | Logic | #Dev | (ps) | (ps) | (nW) | (ns · nW) |
| 3-Input | CNT | CMOS static | 27 | 11.15 | 8.02 | 30.22 | 0.29 |
| NAND | | LUT | 64 | 12.30 | 13.24 | 127.44 | 1.63 |
| | Silicon | CMOS static | 27 | 73.52 | 93.45 | 170.15 | 14.20 |
| | | LUT | 64 | 191.56 | 95.81 | 479.80 | 68.94 |
| 3-Input | CNT | CMOS static | 27 | 11.72 | 6.63 | 27.08 | 0.25 |
| NOR | | LUT | 64 | 12.30 | 13.24 | 127.44 | 1.63 |
| | Silicon | CMOS static | 27 | 156.80 | 47.71 | 107.04 | 10.95 |
| | | LUT | 64 | 191.56 | 95.81 | 479.80 | 68.94 |
| Adder | CNT | CMOS static | 27 | 7.38 | 9.74 | 26.96 | 0.23 |
| Cₒᵤₜ | | LUT | 64 | 12.30 | 13.24 | 127.44 | 1.63 |
| | Silicon | CMOS static | 27 | 134.60 | 56.23 | 132.95 | 12.69 |
| | | LUT | 64 | 191.56 | 95.81 | 479.80 | 68.94 |
| 4-Input | CNT | CMOS static | 44 | 13.04 | 11.14 | 40.85 | 0.49 |
| NAND | | LUT | 160 | 15.99 | 16.70 | 327.43 | 5.35 |
| | Silicon | CMOS static | 44 | 105.50 | 172.46 | 254.23 | 35.33 |
| | | LUT | 160 | 345.12 | 144.06 | 1201.76 | 293.94 |
| 4-Input | CNT | CMOS static | 44 | 16.37 | 8.38 | 37.64 | 0.47 |
| NOR | | LUT | 160 | 15.99 | 16.70 | 327.43 | 5.35 |
| | Silicon | CMOS static | 44 | 363.83 | 70.92 | 170.03 | 36.96 |
| | | LUT | 160 | 345.12 | 144.06 | 1201.76 | 293.94 |
| Adder | CNT | CMOS static | 44 | 14.65 | 12.20 | 48.73 | 0.65 |
| Sum | | LUT | 160 | 15.99 | 16.70 | 327.43 | 5.35 |
| | Silicon | CMOS static | 44 | 442.30 | 88.74 | 375.70 | 99.76 |
| | | LUT | 160 | 345.12 | 144.06 | 1201.76 | 293.94 |

Compared with the existing VLSI programmable fabrics, the embodiments described herein has the potential to reduce the gap between FPGA and ASIC in terms of logic density, performance, and power consumption. For example, by removing the restriction of logic implementation based on LUTs or PLAs and allowing logic implementation in CMOS static logic or any other logic family; replacing a heterogeneous fabric by a homogeneous fabric for minimum layout complexity and ease of technology scaling; and for maximum degree of freedom in configuration without any restriction of logic area vs. routing area ratio, this technology leads to a denser, faster, and less power-consuming programmable fabric. Anti-fuses and/or flash memories also lead to superior design security and soft error immunity.

In this patent, certain U.S. patents, U.S. patent applications, and other materials (e.g., articles) have been incorporated by reference. The text of such U.S. patents, U.S. patent applications, and other materials is, however, only incorporated by reference to the extent that no conflict exists between such text and the other statements and drawings set forth herein. In the event of such conflict, then any such conflicting text in such incorporated by reference U.S. patents, U.S. patent applications, and other materials is specifically not incorporated by reference in this patent.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as examples of embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A reconfigurable fabric comprising rows of PMOS/NMOS floating-gate transistors in a series, with intermediate programmable or fixed vias coupling orthogonal metal wires, wherein a floating-gate transistor is reconfigurable to open, short, or a transistor; and wherein a programmable via is reconfigurable to be open or via.

2. The fabric of claim 1, wherein the programmable vias are anti-fuse based.

3. The fabric of claim 1, wherein the programmable via is reconfigurable using programming methods for NAND flash memory and/or anti-fuse based FPGAs.

4. The fabric of claim 1, further comprising horizontal/vertical polysilicon/metal wires on all layers of different lengths, are coupled by programmable vias formed on the same layer or on adjacent layers.

5. The fabric of claim 1, further comprising floating-gate pass transistors, which couple polysilicon and metal wires and form a crossbar structure in programming, and are turned off in circuit operation.

6. The fabric of claim 5, further comprising floating-gate pass transistors which isolate an anti-fuse in programming.

7. The fabric of claim 1, wherein the programmable fabric is programmable as address decoders of a binary decoder circuit or a hybrid of a binary decoder indicating the least-significant bits and a voltage-controlled nano-addressing circuit indicating the most-significant bits, which comprises two address lines as resistive voltage dividers, gating the orthogonal date lines via two rows of transistors.

8. A reconfigurable fabric comprising alternative rows of PMOS/NMOS flash memory floating-gate transistors in a series, with alternative programmable vias formed by branched-out flash memory floating-gate transistors coupling to orthogonal metal wires, wherein a floating-gate transistor is reconfigurable to open, short, or a transistor, and wherein a programmable via is reconfigurable to be open or via.

9. The fabric of claim 8, wherein the programmable via is reconfigurable using programming methods for NAND flash memory and/or anti-fuse based FPGAs.

10. The fabric of claim 8, further comprising horizontal/vertical polysilicon/metal wires on all layers of different lengths, are coupled by programmable vias formed on the same layer or on adjacent layers.

11. The fabric of claim 8, further comprising floating-gate pass transistors, which couple polysilicon and metal wires and form a crossbar structure in programming, and are turned off in circuit operation.

12. The fabric of claim 11, further comprising floating-gate pass transistors which isolate an anti-fuse in programming.

13. The fabric of claim 8, wherein the programmable fabric is programmable as address decoders of a binary decoder circuit or a hybrid of a binary decoder indicating the least-significant bits and a voltage-controlled nano-addressing circuit indicating the most-significant bits, which comprises two address lines as resistive voltage dividers, gating the orthogonal date lines via two rows of transistors.

14. A uniform array of programmable devices, comprising:
(a) a uniform array of horizontal and vertical pre-routed interconnects, and
(b) a complex programmable device or a floating-gate transistor and two programmable vias at each crosspoint of horizontal and vertical interconnects,
wherein a complex programmable device is reconfigurable to via, open, short, or a transistor, a floating-gate transistor is reconfigurable to open, short, or a transistor, a programmable via is reconfigurable to be open or via.

15. An alternating floating-gate transistors and programmable vias-based compact regular reconfigurable computing platform comprising:
(a) a uniform array of horizontal and vertical pre-routed interconnects, and
(b) alternating floating-gate transistors and programmable vias at crosspoints of horizontal and vertical interconnects,
wherein a floating-gate transistor is reconfigurable to open, short, or a transistor, a programmable via is reconfigurable to be open or via.

16. A compact floating-gate transistor arrays and programmable/fixed vias-based compact regular reconfigurable computing platform, comprising:
a) floating-gate transistor arrays with fixed power, ground, and output routings, and a fixed number (e.g., three or four) of inputs within a cell, and
(b) pre-routed interconnects of various lengths, which are connected by programmable vias, wherein a floating-gate transistor is reconfigurable to open, short, or a transistor, a programmable via is reconfigurable to be open or via.
